(19) United States
(12) Patent Application Publication
(10) Pub. No.: US 2016/0049610 A1
(43) Pub. Date: Feb. 18, 2016

(54) NANOCOMPOSITE, METHOD TO PRODUCE THE SAME, A BARRIER STRUCTURE FOR AN ELECTRONIC DEVICE AND AN OLED COMPRISING THE SAME

(71) Applicant: NEDERLANDSE ORGANISATIE VOOR TOEGEPAST- NATUURWETENSCHAPPELIJK ON-DERZOEK TNO, 's-Gravenhage (NL)

(72) Inventors: STEPHAN HARKEMA, 'S-GRAVENHAGE (NL); NICOLE MARIA MATTHIAS MEULENDIJKS-KIGGEN, 'S-GRAVENHAGE (NL); RENZ JEROEN van Ee, 'S-GRAVENHAGE (NL)

(21) Appl. No.: 14/780,202

(22) PCT Filed: Mar. 25, 2014
(86) PCT No.: PCT/NL2014/050184

§ 371 Date: Sep. 25, 2015

(30) Foreign Application Priority Data
Mar. 25, 2013 (EP) 13160911.7

(51) Int. Cl. H01L 51/52; C08K 3/22; C08K 9/04; H01L 51/00

(52) U.S. Cl. CPC H01L 51/5256; H01L 51/0097; H01L 51/5275; H01L 51/0084; C08K 3/22; C08K 9/04; H01L 51/0034; H01L 2251/5369; H01L 2251/5338; C08K 2003/2241; C08K 2003/2206

(57) ABSTRACT

The present invention relates to a nanocomposite comprising primary nanoparticles having a particle size of less than 10 nm said primary nanoparticles forming agglomerates with a bimodal size distribution, dispersed in a polymer matrix, wherein the nanocomposite comprises 10-80 wt. % of the agglomerates having a particle size of less than 30 nm and less than 20 wt. % of the agglomerates having a particle size of at least 100 nm, preferably at least 400 nm, based on the total weight of the agglomerates. The surface of the nanoparticles can be modified with a surface modifier. The composition can advantageously be used as an organic layer between two inorganic layers in high-refractive barrier structures for electronic devices such as organic light-emitting diode (OLED).

### FIELD OF THE INVENTION

The invention is in the field of light-emitting diodes (LEDs), particularly organic light-emitting diodes (OLED), and further relates to a composition comprising nanoparticles (nanocomposite), a method to produce the same and to the application of said composition in barrier structures of electronic devices, preferably OLED.

### BACKGROUND TO THE INVENTION

Organic light-emitting diodes (OLEDs) potentially offer many advantages over other display technologies such as liquid crystal displays (LCDs), as they allow to produce thin, light-weight and flexible displays. An advantage of OLED-based displays, as compared to LCDs is that they avoid the need for backlight, which makes LCDs high energy consumptive.

OLEDs typically include an anode formed from a transparent electrically conductive material (for example, indium tin oxide (“ITO”)), a metal cathode (for example, lithium, magnesium, indium, calcium, or barium), and organic layers disposed between the cathode and the anode. Application of an electric field across the cathode and anode causes electrons and holes respectively to be injected into the organic layers and move through the device. Emitted light can exit the OLED through the (semi-)transparent anode and/or cathode.

To provide sufficient lifetime of an OLED, barrier structures are used to protect the vulnerable organic layers against the moisture and oxygen from the environment. Barrier structures usually comprise one or more inorganic thin layers, or may comprise organic and inorganic thin layers alternating each other.

An aim of the present invention is to provide a barrier structure for electronic devices such as OLEDs. In particular, the invention seeks to provide a composition for a barrier structure that possesses good barrier properties such as low water and oxygen permeation and at the same time has excellent optical properties and can be used in high efficiency OLEDs. Another aim of the present invention is to provide a barrier structure that can be used in flexible OLEDs.

### SUMMARY OF THE INVENTION

In order to better address one or more of the foregoing desires the invention provides, in one aspect, a nanocomposite comprising primary nanoparticles having a particle size of less than 10 nm, said primary nanoparticles forming agglomerates dispersed in a polymer matrix, wherein the nanocomposite comprises 10-80 wt. % of agglomerates having a particle size of less than 30 nm and less than 20 wt. % of agglomerates having a particle size of at least 100 nm, preferably 400 nm, based on the total weight of the agglomerates.

In a further aspect, the invention provides a method of manufacturing of the nanocomposite of the invention, comprising the steps of:

(a) providing a dispersion of nanoparticles of an inorganic material with a hydrophobically modified surface in a medium, wherein the dispersion comprises 10-80 wt. % of particles having a particle size of less than 30 nm and less than 20 wt. % of particles having a particle size of at least 100 nm, based on the total weight of the agglomerates,
(b) introducing the dispersion of nanoparticles into a curable organic substance, and
(c) curing the organic substance.

In another aspect, the invention provides a nanocomposite obtainable by the method of the invention. In a yet another aspect, a barrier structure for an electronic device is provided, said barrier structure comprising the nanocomposite layer according to the invention, formed between two inorganic layers.

In a further aspect, the invention provides an organic light-emitting diode (OLED) comprising: a cathode layer, an organic electroluminescent layer, an anode layer, and a barrier structure according to the invention.

### DETAILED DESCRIPTION OF THE INVENTION

The present invention thus provides a nanocomposite that is particularly suitable for a barrier structure in electronic devices, which nanocomposite comprises a matrix and nanoparticles dispersed in the matrix. The nanoparticles show a bimodal (or plurimodal) particle size distribution, which provides for the advantageous optical properties of the nanocomposite.

The nanoparticles embedded in the matrix preferably comprise inorganic material, such as metals or metalloids, their oxides, sulphides. Also a mixture of different inorganic materials is possible. Under nanoparticles particles are understood that have a diameter of under 1 μm.

In order to increase the refractive index of the matrix, the inorganic material preferably has a refractive index of at least 2, more preferably, at least 2.2. The high refractive index of the material makes it possible that when the nanoparticles are embedded in the matrix, the whole composition has a high refractive index. The refractive index can be measured by common methods known to a person skilled in the art, e.g. by ellipsometry. Examples of suitable inorganic materials with a high refractive index are TiO₂ (anatase, n=2.45; rutile, n=2.70), ZrO₂ (n=2.10), amorphous silicon (n=4.23), PbS (n=4.20) and ZnS (n=2.36). Preferably, rutile TiO₂, anatase TiO₂ or brookite, and more preferably, rutile TiO₂ or anatase TiO₂, is used as the material for the nanoparticles. Also mixtures of different materials can be used.

The nanoparticles with a high refractive index are preferably sufficiently small in size so that no inhomogeneous scattering (Mie-scattering) takes place. The Mie-scattering is usually significant for the particles having a diameter starting from about 100 nm.

The nanoparticles used in the present invention to form a dispersion in the matrix have at least a bimodal particle size distribution. While this in theory can be achieved by using particles have different sizes themselves, it is was found by the inventors to be particularly advantageous and the most practical to achieve such bimodal size distribution by agglomerating primary nanoparticles into clusters having a desired size, which clusters act as individual particles.

Therefore, in the present invention, the nanoparticles are preferably comprised of primary Nanoparticles—that is the particles as synthesized—which preferably have a diameter of less than 10 nm, more preferably, in the range 3-7 nm. The primary particle size is determined by TEM using cryoTITAN, a 300 kV FEG microscope, FEI. The primary nanoparticles are clustered to form larger particles, or agglomerates, whereby the particle size distribution of the agglomerates is such that both small and large agglomerates are preferably present. Under the particle size of an agglomerate the size (diameter) of the agglomerate, as a whole, is meant. Throughout this description, the term “nanoparticle” means both a single particle or an agglomeration of primary nanoparticles.

In particular, a part of the agglomerates has a diameter of preferably less than 80 nm, more preferably less than 50 nm, yet more preferably less than 30 nm. The particle size of the agglomerates can be optimized by sonification, which allows to convert larger agglomerates into agglomerates with a predetermined size. The nanocomposite of the invention preferably comprises 10-80 wt. %, more preferably 30-50 wt. % of such clusters, based on the total weight of the agglomerates. In order to obtain optimal scattering properties, another part of the nanoparticles is present as larger clusters. Preferably, these clusters have a particle size (diameter) of at least 100 nm, more preferably at least 200 nm, yet more preferably at least 400 nm, more preferably at least 500 nm, yet more preferably in the range 400-800 nm. Good results are obtained with clusters having a diameter of about 600 nm. The nanocomposite of the invention preferably comprises at least 0.1 wt. % of such clusters, yet preferably less than 20 wt. %, more preferably less than 5 wt. %, even more preferably 1-3 wt. % of such clusters, based on the total weight of the agglomerates. The particle size of the agglomerates is measured by dynamic light scattering (DLS) using Malvern Zetasizer Nano ZS.

The particle size distribution is preferably bimodal, however, more peaks are not excluded and the size distribution can also be plurimodal, as long as the two above-described peaks are present and have the highest intensities measured by DLS.

The particle size distribution of the nanoparticles can further be characterised with respect to the two highest peaks observed in the particle size distribution pattern. When measured by DLS, the pattern usually shows the intensity of the signal as a function of the particle size. If I₁ and I₂ are the two highest intensities measured with DLS observed at sizes under 30 nm and at sizes at least 100 nm, respectively, and D₁ and D₂ are the corresponding sizes (diameters) at which these peak intensities are measured, then the size ratio of the two peaks is D₂/D₁. It was observed that this size ratio is preferably in the range 5.5-8, more preferably 6-7.5. The size ratio can also be converted to a volume ratio V₂/V₁, wherein volumes V₁ and V₂ are calculated in nm³ from the corresponding diameters D₁ and D₂. The volume ratio is preferably in the range 100-1000, preferably 250-400.

For optimal dispersion properties, the nanoparticles used in the present invention preferably comprise surface modifiers to make the nanoparticles hydrophobic. Without surface modification, the nanoparticles would only be dispersible in hydrophilic solvents such as water and alcohols, which is not practical. Because of the modifiers, the nanoparticles can be dispersed in hydrophobic and apolar solvents (e.g. hydrocarbons such as toluene, xylene; or 1-butanone).

Modifiers should adhere to the nanoparticles. Preferably, the modifiers react with hydroxyl-groups at the surface of the nanoparticles (in case the nanoparticles contain metal oxides, which are usually synthesized in an aqueous medium). Suitable compounds are for example phosphonic acids, boronic acid, carboxylic acids such as acetic acid, oleic acid, amines such as alkyl amines Preferably, carboxylic acids having long chains (fatty acids), such as at least C10, preferably at least C14, more preferably at least C18, such as oleic acid are used. Excellent results are obtained with oleic acid.

In addition to the nanoparticles with a high refractive index as described above, the matrix can also comprise nanoparticles with a lower refractive index (lower than 2) that may be used for other properties, e.g. moisture gettering. An example of such material is CaO (n=1.8). In a preferred embodiment, the matrix comprises TiO₂ (either rutile or anatase) and CaO nanoparticles. Preferably, the nanocomposite comprises 0.01-15 wt. %, preferably 2-15 wt. %, more preferably 5-10 wt. % of CaO nanoparticles for a layer with a thickness of about 20 micron. These CaO nanoparticles preferably have a diameter of less than 500 nm, more preferably less than 200 nm, most preferably under 100 nm, such as 20-50 nm. Such small nanoparticles do not contribute to light scattering and thus are as such “invisible”. This effect is achieved if the difference with the refractive index of the matrix is small, such as for example 0.05. In case of CaO particles, the matrix can have in this case a refractive index of about 1.75.

The nanoparticles used in the present invention are dispersed in a matrix. The matrix is preferably an organic matrix, and more preferably a polymer matrix. Such matrix can, for example, be obtained by curing a curable organic compound, e.g. by polymerization of monomers and/or by cross-linking of polymers.

The nanocomposite having the matrix in its cured state preferably has a refractive index of at least 1.5, more preferably at least 1.7, most preferably at least 1.75. Optimal results are obtained when the matrix has a refractive index of at least 1.75-1.8. Therefore, high-refractive index polymers are especially suitable as the matrix in the present invention.

The polymers suitable for the matrix are preferably polymers having polar groups. Examples of suitable materials for the matrix are acrylates such as aliphatic or aromatic epoxy acrylates, urethane acrylates, polyester acrylates, polyether acrylates, saturated hydrocarbon acrylates. Another group of suitable matrix materials are polysiloxanes. Good results are obtained with aromatic polysiloxanes such as benzyl polysiloxane. Also polyimides are suitable as a polymer matrix for nanoparticles. Preferably, acrylate or acrylate-based matrix is used. The refractive index of the polymers is preferably 1.2-1.6, more preferably 1.4-1.6. Yet more preferably, the refractive index of the polymer of the matrix is at least 1.5.

The nanocomposite of the invention is preferably made in the form of a layer. Under layer it is understood a region of a given material whose thickness is small compared to both its length and width. Examples of layers include sheets, foils, films, laminations, coatings, and so forth. As used herein a layer need not be planar, but can be bent, folded or otherwise contoured, for example, to at least partially envelop another component. The layer according to the invention preferably has a thickness of 1-1000 micron, more preferably 1-100 micron, yet more preferably 2-50 micron, and more preferably 5-20 micron.

The amount of the agglomerated particles may depend on the thickness of the layer. For a layer with a thickness about 100 micron, it is preferred to have 0.1-1 wt. % of the particles in agglomerates with a diameter of at least 400 nm, preferably 0.2-0.8 wt. %. At a concentration of less than 0.1 wt. % the resulting layer would not exhibit sufficient scattering. At values above 1 wt. % the scattering may be too high and cause optical losses. For a layer with a thickness about 20 micron, preferably 0.4-5 wt. % (0.05-1.5 vol. %) of the nanoparticles is agglomerated in agglomerates with a diameter of at least 400 nm. For thinner layers (5-20 micron) the concentration may be 2-20 wt. %. Also combinations of several layers with different particle concentrations are possible.

The particular distribution of the nanoparticles in the matrix is characterized by an optimal ratio of large versus small agglomerates as discussed above, which provides for excellent optical characteristics of the resulting system. In particular, the organic layer prepared from the described composition has a high refractive index of the organic layer and at the same time it exhibits high out-coupling efficiency when used in barrier layers for electronic devices.

In another aspect, the present invention provides a method of manufacturing of the nanocomposite of the invention, comprising the steps

(a) providing a dispersion of nanoparticles of an inorganic material with a hydrophobically modified surface in a medium, wherein the dispersion comprises 10-80 wt. % of particles having a particle size of less than 30 nm and less than 20 wt. % of particles having a particle size of at least 100 nm, based on the total weight of the agglomerates,

(b) introducing the dispersion of nanoparticles into a curable organic substance, and

(c) curing the organic substance.

The dispersion used in step (a) can be prepared in many ways. Several approaches that showed good results are described herein-below.

In one such approach, the steps comprise:

(i) providing of a dispersion of inorganic nanoparticles having a monomodal particle size distribution,

(ii) treating of the nanoparticles with a surface modifier to make these hydrophobic, and

(iii) adding a polar protic solvent to obtain a dispersion of modified inorganic particles having a bimodal particle size distribution.

Preferably, to provide the dispersion of inorganic nanoparticles, these are synthesized in a solution. This preferably takes place in an aqueous phase. An advantage of the aqueous phase is that inorganic particles, for example TiO₂, are usually well dispersible in this phase. The obtained primary nanoparticles preferably have a particle size of less than 10 nm each and may form bigger clusters which show monomodal particle size distribution. The dispersion should be stable, e.g. it should not show immediate sedimentation. Preferably, the highest intensity peak of the monomodal particle size distribution as measured by DLS lies within the range 10-100 nm, preferably, 20-80 nm, more preferably 30-60 nm.

In a following step, the nanoparticles are modified with a surface modifier to be compatible with the curable organic substance used to create the nanocomposite. Suitable surface modifiers are described herein-above. The modification typically takes place by combining of the dispersion of non-modified nanoparticles in an aqueous medium with the surface modifier, preferably together with an alcohol. Particularly, methanol showed good results when used with carboxylic acids such as oleic acid. It is believed by the inventors that an alcohol ensures a better dispersability of the modified nanoparticles, for example in case of long carboxylic acid chains used for surface modification, these are hydrophobic and less compatible with water. The dispersion of the modified nanoparticles may look like a paste which is preferably not dried until the next step.

In a further step, which is optional yet preferred, a solvent compatible with the curable organic substance is added to the dispersion of the modified nanoparticles. This is preferably an apolar solvent, which may be a hydrocarbon, preferably aromatic hydrocarbon, or other suitable solvents. Good results are achieved with toluene. Preferably, the added solvent is also compatible with the modified nanoparticles.

In a subsequent step, a polar protic solvent is added to the dispersion of the modified nanoparticles. Without wishing to be bound by any theory, the present inventors believe that because the surface-modified nanoparticles have a lower compatibility with the polar protic solvent, the solvent will have the effect of changing a monomodal particle size distribution into a bimodal, caused by redistribution of the particles between smaller and bigger clusters. This re-aggregation will for example result in the formation of larger clusters having a particle size of 100 nm and more, preferably at least 200 nm, more preferably at least 400 nm. At the same time also smaller clusters having a particle size of less than 30 nm are formed. Eventually, in this step, a dispersion of nanoparticles of an inorganic material in a medium is obtained, wherein the dispersion comprises 10-80 wt. % of particles having a particle size of less than 30 nm and less than 20 wt. % of particles having a particle size of at least 100 nm, based on the total weight of the agglomerates. Suitable amounts of the polar protic solvent to be added can easily be determined by a skilled person by routine experimentation. In this preparation method, the “particles” are in fact aggregates of primary nanoparticles with different “particle” sizes.

The obtained dispersion can further be used in steps (b) and (c) as described above to obtain the end product, the nanocomposite.

The step of creating of at least a bimodal distribution of the nanoparticles is not necessarily the last one before introducing the nanoparticles in the organic curable matrix. In the method described herein-above, the bimodal distribution can be effected at other stages as well. For example, as believed by the inventors, already during the synthesis step, a bimodal distribution can be effected by the use of different solvents/antisolvents. During the surface modification step, the bimodal distribution can be obtained by the use of solvents in combination with antisolvents, or by changing pH.

It is however highly preferred to create the desired bimodal particle size distribution as late as possible in the process, preferably just before the introduction of the dispersion into the matrix to be cured. An important reason for that is that this allows to create a dispersion in a more controlled way so that the desired particle size distribution is achieved and also introduced in the matrix. More processing steps in between could lead to the change of the particle sizes, e.g., due to unwanted agglomeration, and thus to a more difficult control of the resulting sizes.

For example, in one embodiment, the bimodal distribution is obtained before the surface modification step. Such method thus comprises the steps of:

(a) providing a dispersion of nanoparticles of an inorganic material in an aqueous medium, wherein the dispersion comprises 10-80 wt. % of particles having a particle size of less than 30 nm and less than 20 wt. % of particles having a particle size of at least 100 nm, preferably at least 400 nm, based on the total weight of the agglomerates,

(b) adding a surface modifier to the dispersion thereby obtaining modified nanoparticles,

(c) dispersing the modified nanoparticles in a curable organic substance, and

(d) curing the organic substance.

The nanoparticles comprise an inorganic material, which preferably has a refractive index of at least 2, as described herein-above.

In one embodiment, the particles with suitable particle sized can be used from commercial sources. In a highly preferred embodiment, however, the nanoparticles used in the present invention comprise primary nanoparticles, agglomerated in clusters with different sizes, as described above. Preferably, the primary nanoparticles are synthesized in situ as it offers more possibilities to control the agglomeration of the particles. The agglomeration into desired cluster sizes can be suitably controlled by the pH of the aqueous medium or by adding suitable solvents or antisolvents as described above. The suitable pH ranges, solvent and antisolvents may depend on the inorganic material used and can be determined by a skilled person by way of routine experimentation, based on the desired agglomerates size that should be obtained.

As a guideline for the pH method, the following procedure may be followed. The dispersion of nanoparticles with a bimodal size distribution can be provided according to the method comprising:

(i) providing a dispersion of primary nanoparticles of an inorganic material in an aqueous medium, said primary nanoparticles having a particle size of less than 10 nm,

(ii) adjusting the pH to a value below 4 thereby forming agglomerates having a particle size of less than 30 nm, and

(iii) adjusting the pH to a value at least 4 thereby forming agglomerates having a particle size of at least 100 nm, preferably at least 400 nm.

In step (ii) the pH is adjusted to a value which should lead to the formation of agglomerates with a particle size of less than 30 nm. In some embodiments, it is preferred to use pH 1-3 in step (ii). Acidic pH is advantageous for the controlled agglomeration of the primary nanoparticles. In case of TiO₂, by using a pH lower than 4, agglomerates can be obtained with a particle size less than 70 nm. Most preferably, a pH of 2-3.5 can be used to obtained agglomerates with a particle size less than 60 nm. This acidification step is advantageous to achieve a particular particle size distribution of the nanoparticles that is maintained after the surface modification step.

It is to be understood that step (ii) of adjusting the pH may be omitted if the required pH is already achieved in step (i), e.g. if step (i) comprises synthesis of the primary nanoparticles in an acidic environment. In step (ii) clusters, or agglomerates, having a particle size of less than 30 nm are formed.

In a following step, step (iii), the pH is adjusted to a value higher than in step (ii) and preferably to a pH of at least 4, wherein the formation of agglomerates with a particle size of at least 100 nm (preferably at least 400 nm) takes place. More preferably, the pH is 3-7 in this step, more preferably 4-5. This step can be omitted if commercial agglomerates or particles with a particle size of at least 400 nm are used. In this case, in step (iii) these agglomerates or particles are added. The skilled person is able to adjust the parameters in order to obtain a dispersion with the desired concentration of small and large clusters/aggregates or particles. Although in theory being possible, adding of commercial agglomerates or particles with a particle size of at least 400 nm is however not practical and therefore not recommended. The addition of such particles will influence the size distribution in a less controlled way than in the way described above. Moreover, the added particles may cause aggregation of the smaller particles or aggregate themselves. For these reasons it is highly preferred to create the bimodal distribution in situ.

As a result of the above steps, a dispersion having a bimodal particle size distribution is obtained. In a following step, the nanoparticles are modified with a surface modifier. Preferably, this is done in solution, wherein the modifier and the particles are solved or dispersed in a suitable solvent or a mixture of solvents. Suitable solvents are for example, water and alcohols such as methanol. For example, a water/alcohol mixture can be used.

After the nanoparticles dispersion is provided, it is introduced (dispersed) into the matrix, which is step (b) of the method according to the invention. In a next step, the modified nanoparticles are dispersed in a matrix material. A curable organic substance is used to produce the matrix material. Curable preferably means a compound that can be transformed in a substantially non-flowing substance (cured substance) by chemical or physical treatment. In particular, curable may mean polymerisable and/or cross-linkable substance. In its cured state, the organic substance preferably has a refractive index of 1.4-1.6, more preferably at least 1.5.

In a separate embodiment, the modified nanoparticles can be mixed with other nanoparticles (such as CaO) before being dispersed. The dispersion in the matrix can be done, for example, by mixing the nanoparticles with a solvent compatible with the curable organic substance and then dispersing the coated nanoparticles in the curable organic substance. If acrylates are used as a matrix material, suitable solvents are for example toluene, o-xylene, mesitylene, pentanol. Preferably, toluene is used. Since the organic substance may be viscous, the solvent is used to make it less viscous and to improve the distribution of the nanoparticles in the matrix. The volume fraction of the nanoparticles in the matrix is preferably in the range 10-80 vol. %, more preferably 30-60 vol. %.

The matrix with the dispersed modified nanoparticles is then cured, e.g. by polymerisation and/or cross-linking of the organic curable substance. Any suitable method for polymerisation and cross-linking can be used, e.g. UV or thermal hardening. Before curing the solvent is preferably removed from the system, e.g. by evaporation, preferably using a nitrogen flow.

When the composition according to the invention is used in the form of a layer, e.g. in an electronic device, the above method includes an additional step of forming a layer of the curable organic substance comprising the coated nanoparticles dispersed therein, which step is carried out before the curing step. The layer is preferably formed in a substrate using spin-coating or dipcoating. Also other techniques such as doctor blading, continuous roll-to-roll or sheet-to-sheet printing or coating are suitable.

The layer comprising the nanocomposite of the invention is particularly suitable to be used in a barrier system for electronic devices such as organic photovoltaics (OPV) and especially organic light-emitting diodes (OLED). The term “organic light-emitting diode” (OLED) as used in this description includes both small metal-organic molecule OLED and polymeric OLED. This means that the material in the OLED that is capable of emitting light, is an organic or polymeric semiconductor material that, upon application of a proper voltage, will emit light. In short, this is referred to as a light-emitting material.

Particularly, the layer is suitable as a high refractive index scattering layer in glass-based or plastic substrate OLED, preferably as a high refractive index scattering barrier and/or encapsulation layer in OLED in all designs (top emission, bottom emission, transparent). The layer can also be used as a light in-coupling layer in photovoltaic devices, in beam shaping in (flexible) OLED.

In a further aspect, therefore, the present invention provides a barrier system for an electronic device, preferably OLED, which comprises the layer as described above formed (located) between two inorganic layers.

The first and/or second inorganic layer may for example be a metal or oxide, metal nitride, metal carbide, metal oxynitride, or a combination thereof. The term metal here also includes metalloids such as silicon Si. Particularly suitable materials are silicon oxide (SiO₂), aluminium oxide (Al₂O₃), titanium oxide (TiO₂), aluminium nitride (AlN), silicon nitride (SiN), silicon carbide (SiC), silicon oxynitride (SiON) and combinations thereof In a preferred embodiment, both the first and the second inorganic layers are SiN layers.

The inorganic layers are preferably thinner than the organic layer. In a preferred embodiment, the inorganic layers have a thickness in the range of 1 to 1000 nm, preferably in the range of 10 to 300 nm.

According to a still further aspect, the present invention provides an electronic device comprising the barrier structure according to the invention. The electronic device is preferably an organic photovoltaics (OPV), more preferably an organic light-emitting diode (OLED). Such an organic light-emitting diode (OLED) comprises a cathode layer, an organic electroluminescent layer, an anode layer, and a barrier structure as described above. Also several barrier structures according to the invention can be present.

In a preferred embodiment, the OLED comprises two barrier structures according to the invention, wherein one barrier structure is placed on the outer side of the cathode layer and the other barrier structure is placed on the outer side of the anode layer. In this way, two barrier layers according to the invention provide encapsulation for the OLED. Such encapsulation system is particularly useful for transparent OLED.

The invention will now be illustrated in the following non-limiting examples.

### EXAMPLES 1

### Synthesis and Modification of TiO₂ particles

Commercially available TiO₂ particles were obtained from Plasmachem and Iolitec and were claimed to have a particle size of <30 nm (average). These particles were supplied in dry form and can be well dispersed in water.

TiO₂ nanoparticles were synthesized following the procedure in article; colloids and surfaces A: Physicochem. Eng. Aspects, 372 (2010) 41-47, “Small-molecule in situ stabilization of TiO₂ nanoparticles for facile preparation of stable colloidal dispersions”.

1 ml of TiCl₄ (Fluka>99%, 50 ml, 89545) is added dropwise to 5 ml (3.95 g) ethanol (Biosolve absolute dehydrated AR, 05250502) under nitrogen environment, during addition the colour changes to yellow (transparent) and the temperature of the solution rises. After stirring for about 5-10 minutes 20 ml hydrated benzyl alcohol (Sigma reagent plus>99%, 10,800-6) (95% wt) is added under nitrogen environment. During addition the colour changes from yellow to dark red (transparent). The solution is stirred for 5 minutes after which it is placed in an oil bath at a temperature of 85° C. for 8 hours under continuous stirring.

After 5 minutes of heating again a colour change is seen from dark red back to yellow (transparent). The yellow colour changes in time to yellow bluish to white (2 hours). The reaction is proceeded for 8 hours after which it is stopped. Precipitated material is seen after the stirring is stopped. The dispersion is centrifuged (30 min, 4450 rpm) and washed 2 times with diethyl ether (with centrifuging). The obtained white powder is dried in air at r.t. to remove diethyl ether. The white powder is dispersible in water obtaining a stable white dispersion.

### EXAMPLE 2

### Modification of TiO₂-Particles Using Oleic Acid

The synthesized and also the commercial unmodified titanium nanoparticles (8 g) were dispersed in water/methanol (70.5 ml/240 ml) (samples NM334A, NM334B1 and NM334C1) and in water (samples NM334B2 and NM334C2) using an ultrasonic tip (Branson) with an output of 20% for 2 minutes. Methanol was added to the mixtures NM334B2 and NM334C2 and the obtained dispersion was again treated with an ultrasonic tip.

An excess of oleic acid (29 g) in methanol (80.5 ml) was added to the resulting opaque dispersion, the particles precipitated directly after addition. The excess is calculated based on what is needed to cover all the surface area of the particles plus some extra amount. The modified particles were purified (excess of oleic acid was removed) by centrifugation and washing with methanol three times. Methanol was removed and the resulting modified particles were dispersed in toluene. Solid content of the dispersions was determined.

Size distributions of all oleic acid modified TiO₂ nanoparticles was measured using Dynamic Light Scattering. The most optimal dispersion (NM334B2 according to DLS) was treated with different types of solvents (non-polar (Hexane), polar aprotic (THF) and polar protic (EtOH, pentanol)) in order to investigate the possibility of obtaining bi-modal distributions. The nanoparticles size distribution as a function of solvent treatment is measured using DLS. All samples were measured at room temperature. Table 1 summarizes the samples and the treatments.

TABLE 1

| | Sample | Sample | Sample | Visual |
|---|---|---|---|---|
| # | label | description | treatment | inspection |
| 1 | NM334A1 | TiO2~oleic | Dispersion in | White, |
| | | (Iolitec) | toluene | sedimenting |
| 2 | NM334B1 | TiO2~oleic (TNO, | Dispersion in | Clear |
| | | RJ110313-1) | toluene | |
| 3 | NM334B2 | TiO2~oleic (TNO, | Dispersion in | Clear |
| | | RJ110313-1) | toluene | |
| 4 | NM334C1 | TiO2~oleic | Dispersion in | White, |
| | | (Plasmachem) | toluene | stable |
| 5 | NM334C2 | TiO2~oleic | Dispersion in | White, |
| | | (Plasmachem) | toluene | stable |
| 6 | NM334B2 | TiO2~oleic (TNO, | 0.5 ml/toluene + | Clear |
| | | RJ110313-1) | 0.5 ml Hexane | |
| 7 | NM334B2 | TiO2~oleic (TNO, | 0.5 ml/toluene + | Clear |
| | | RJ110313-1) | 1.0 ml Hexane | |
| 8 | NM334B2 | TiO2~oleic (TNO, | 0.5 ml/toluene + | Clear |
| | | RJ110313-1) | 1.5 ml Hexane | |
| 9 | NM334B2 | TiO2~oleic (TNO, | 0.5 ml/toluene + | Clear |
| | | RJ110313-1) | 0.5 ml THF | |
| 10 | NM334B2 | TiO2~oleic (TNO, | 0.5 ml/toluene + | Clear |
| | | RJ110313-1) | 1.0 ml THF | |
| 11 | NM334B2 | TiO2~oleic (TNO, | 0.5 ml/toluene + | Clear |
| | | RJ110313-1) | 1.5 ml THF | |
| 12 | NM334B2 | TiO2~oleic (TNO, | 0.5 ml/toluene + | Clear |
| | | RJ110313-1) | 0.5 ml Ethanol | |
| 13 | NM334B2 | TiO2~oleic (TNO, | 0.5 ml/toluene + | Clear |
| | | RJ110313-1) | 1.0 ml Ethanol | |
| 14 | NM334B2 | TiO2~oleic (TNO, | 0.5 ml/toluene + | Clear |
| | | RJ110313-1) | 1.5 ml Ethanol | |
| 15 | NM334B2 | TiO2~oleic (TNO, | 0.5 ml/toluene + | Clear |
| | | RJ110313-1) | 0.5 ml Pentanol | |
| 16 | NM334B2 | TiO2~oleic (TNO, | 0.5 ml/toluene + | Clear |
| | | RJ110313-1) | 1.0 ml Pentanol | |
| 17 | NM334B2 | TiO2~oleic (TNO, | 0.5 ml/toluene + | Clear |
| | | RJ110313-1) | 1.5 ml Pentanol | |

### EXAMPLE 3

### DLS Size Measurements

Protocol sizing measurements:

Size measurements of particle dispersions were analyzed using a Malvern nano Zetasizer. Size measurements were performed in clear disposable zeta cuvettes (DTS1060C) at 25° C. using an equilibration time of 2 min. Each measurement was repeated 3 times having a delay of 10s.

Equipment settings are shown below:

Dispersant: toluene

Dispersant RI: 1.496

Viscosity (cP): 0.590

Material RI: 2.00 Material abs: 0.1

Position: 4.65

Measurement angle: 173° Backscatter

Measurement duration: automatic

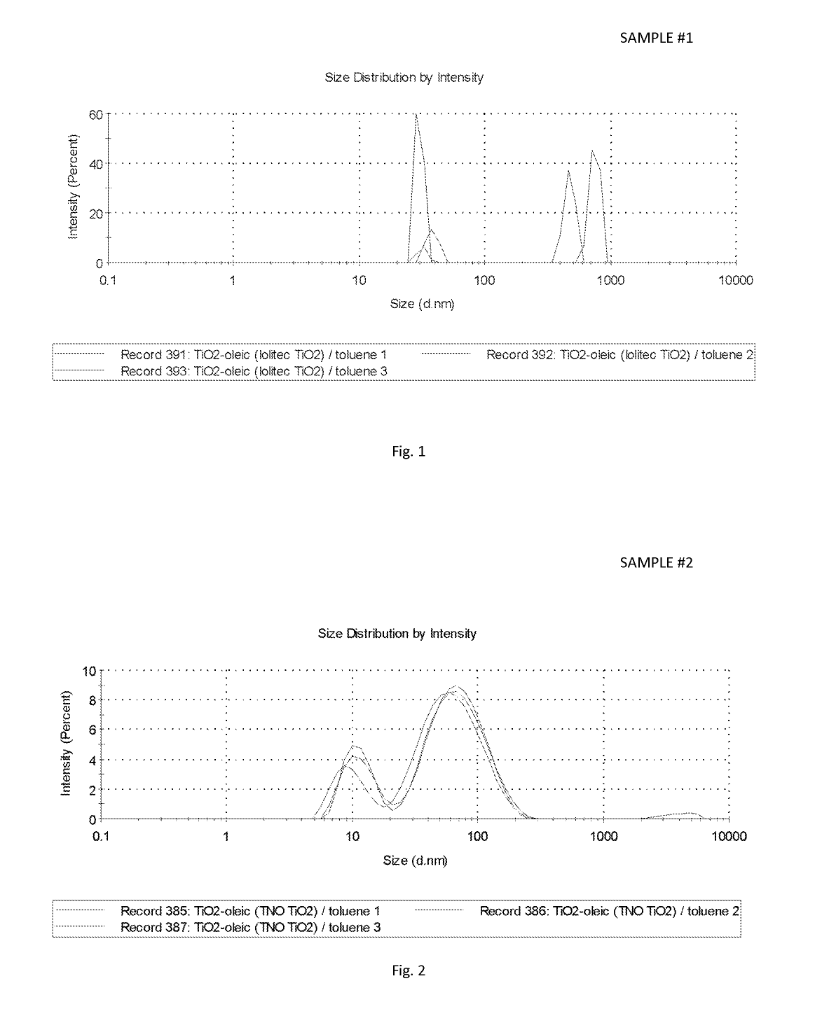

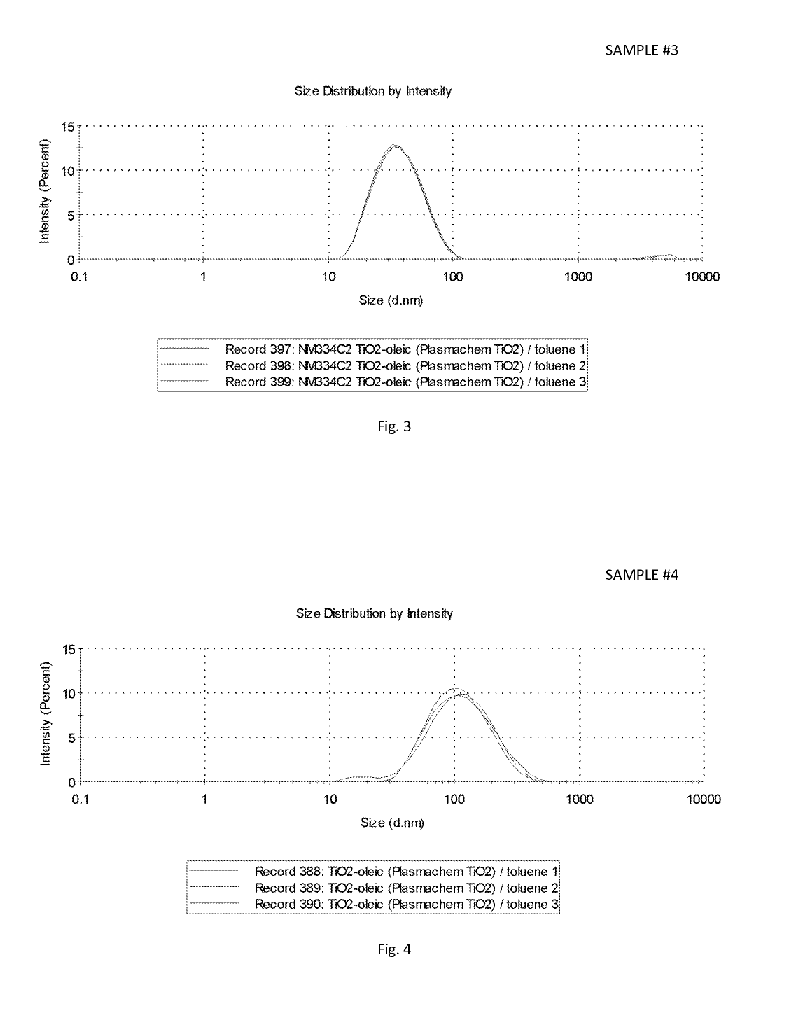

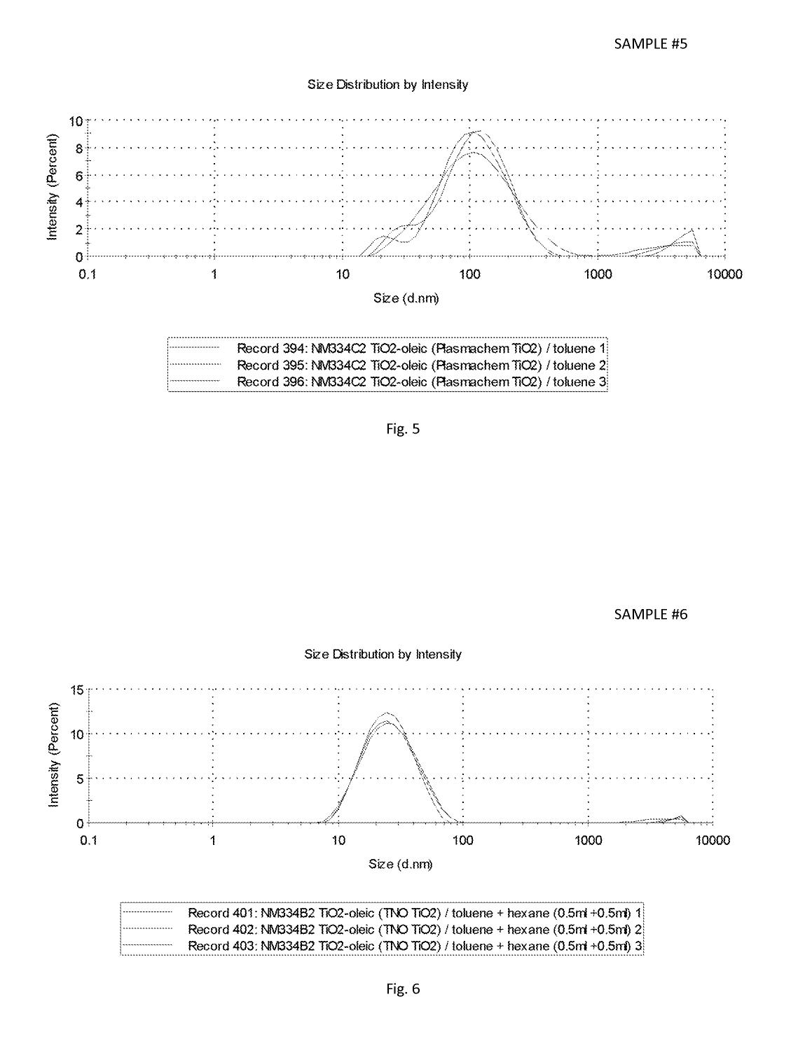

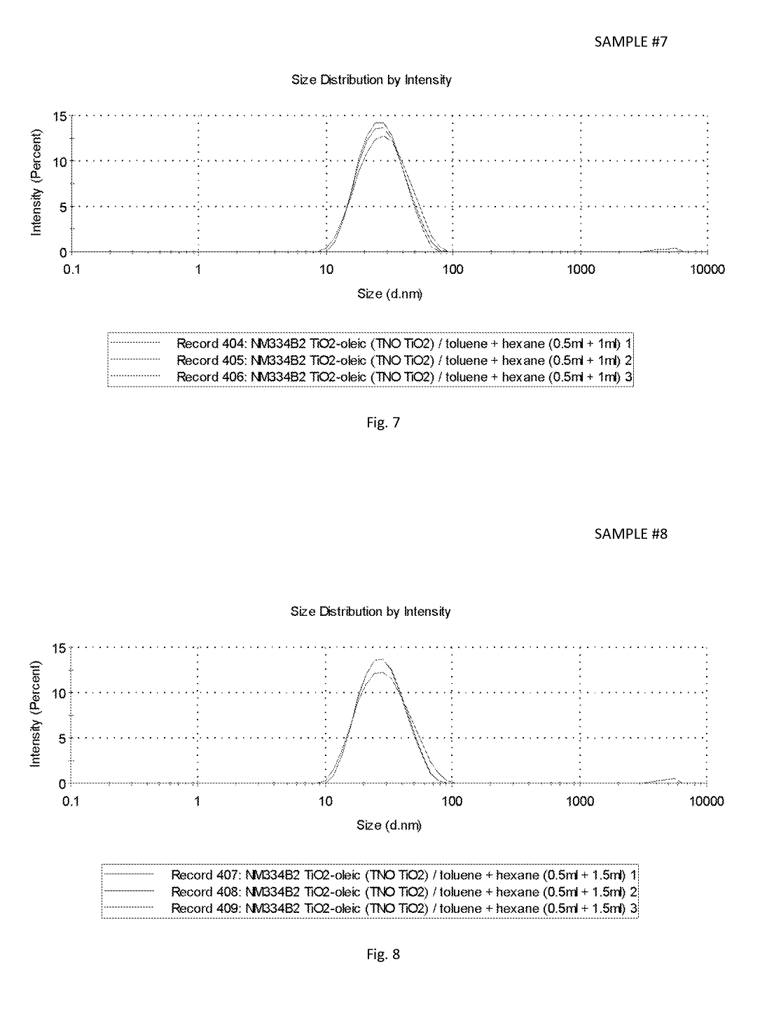

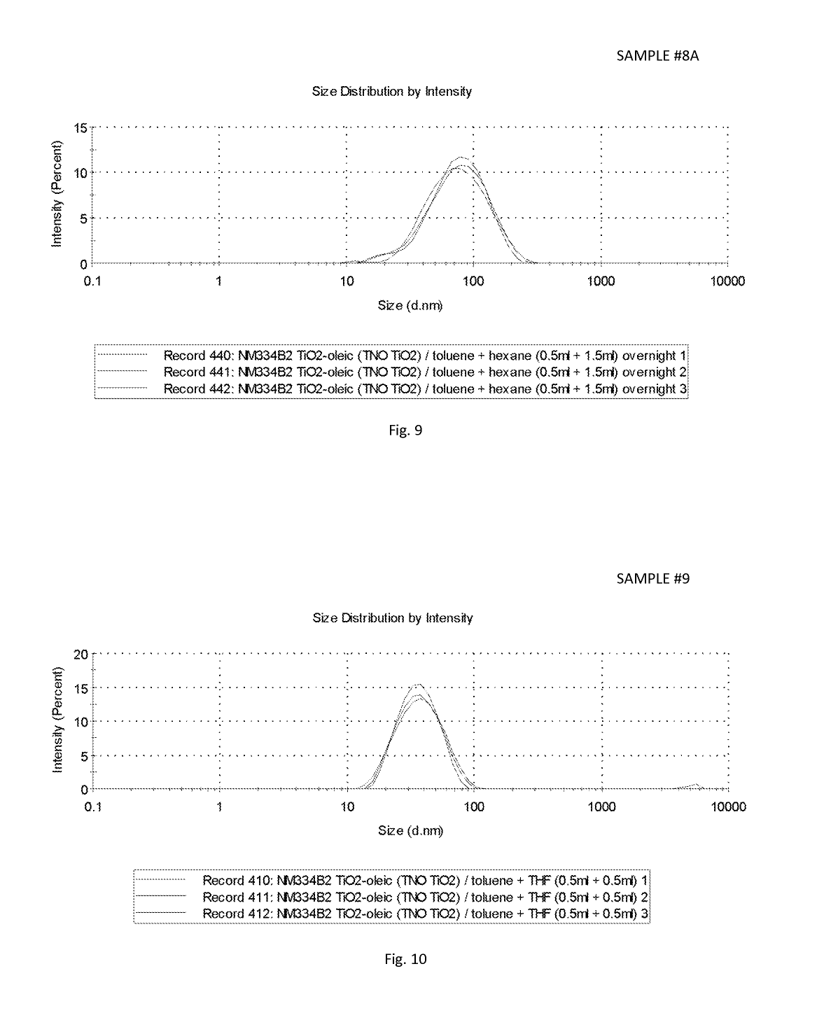

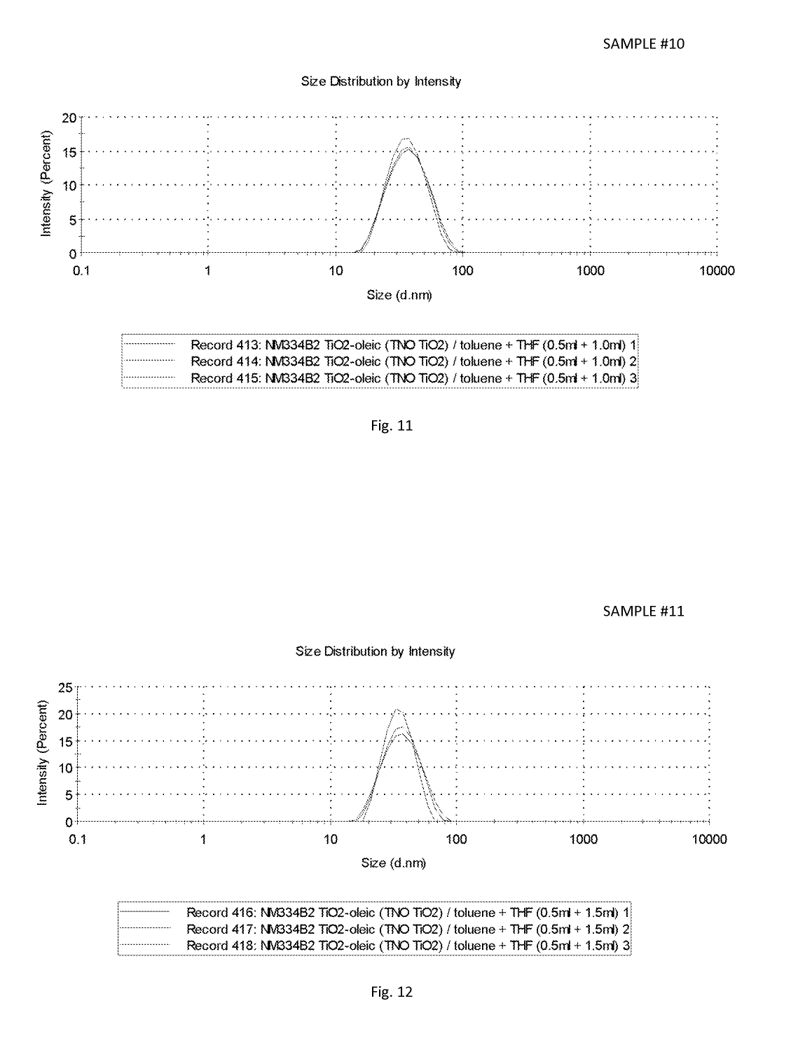

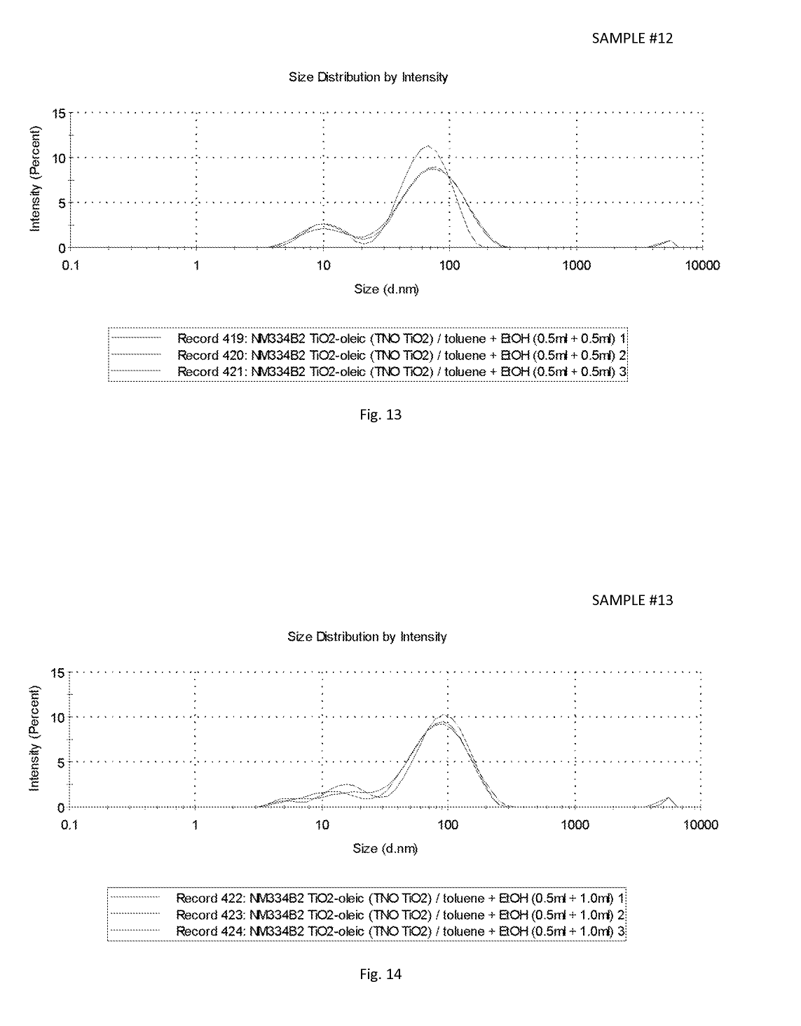

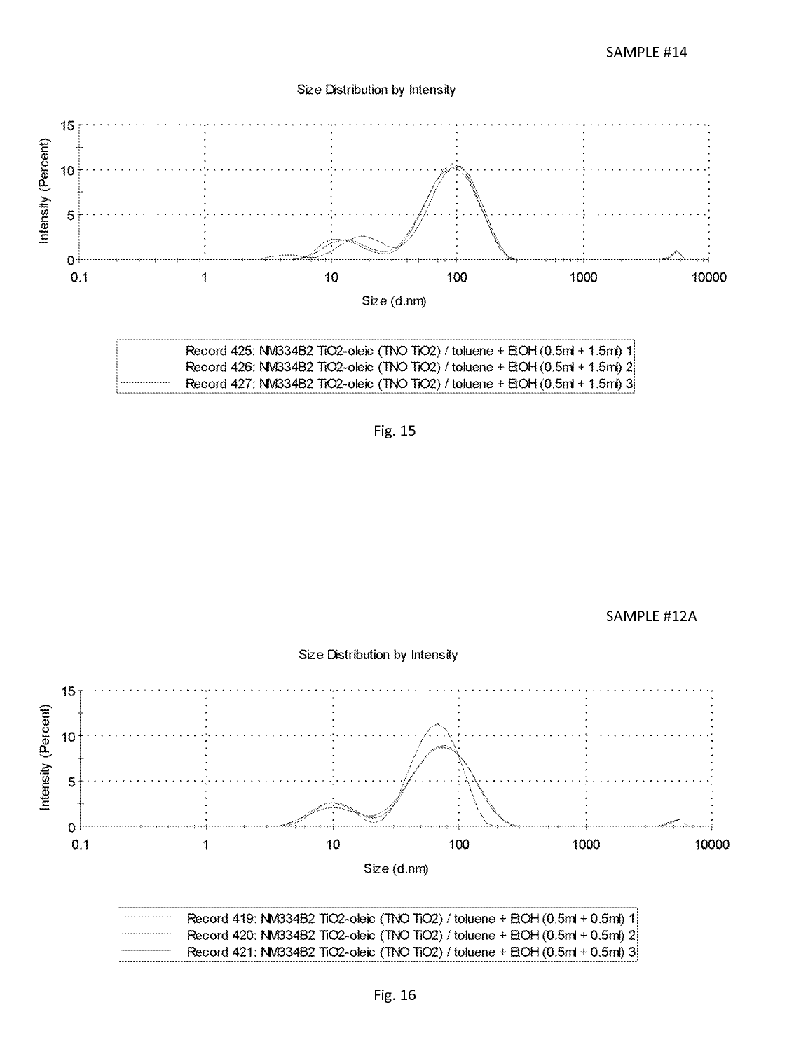

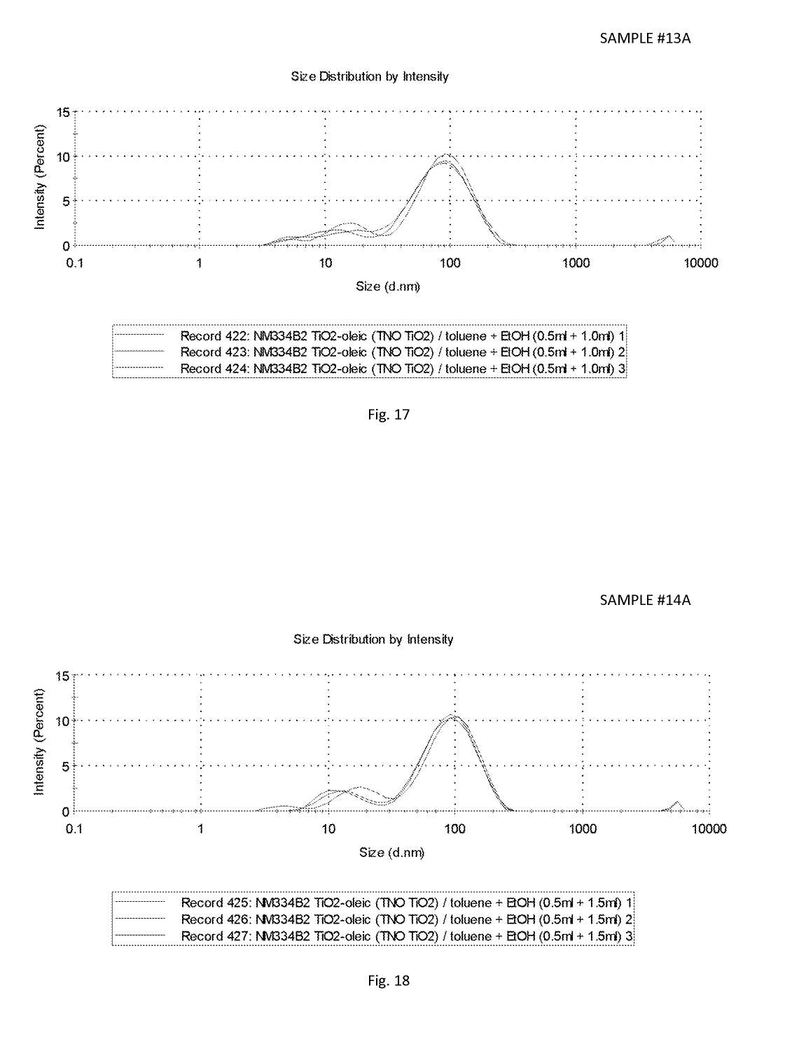

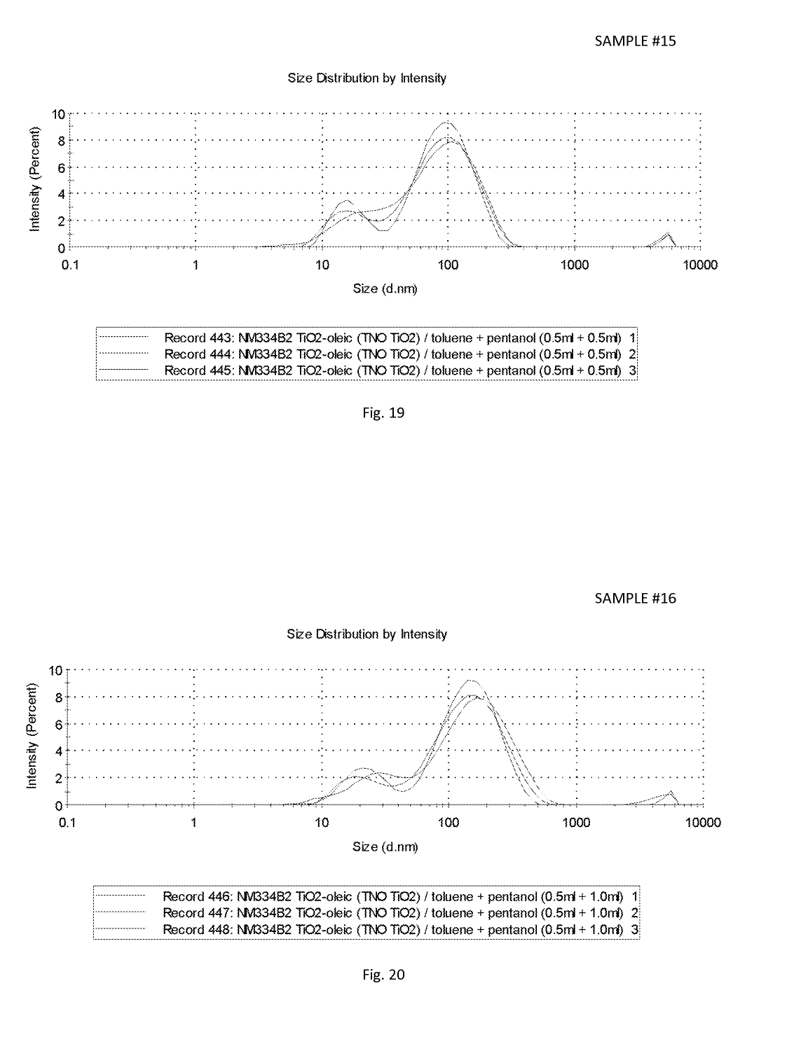

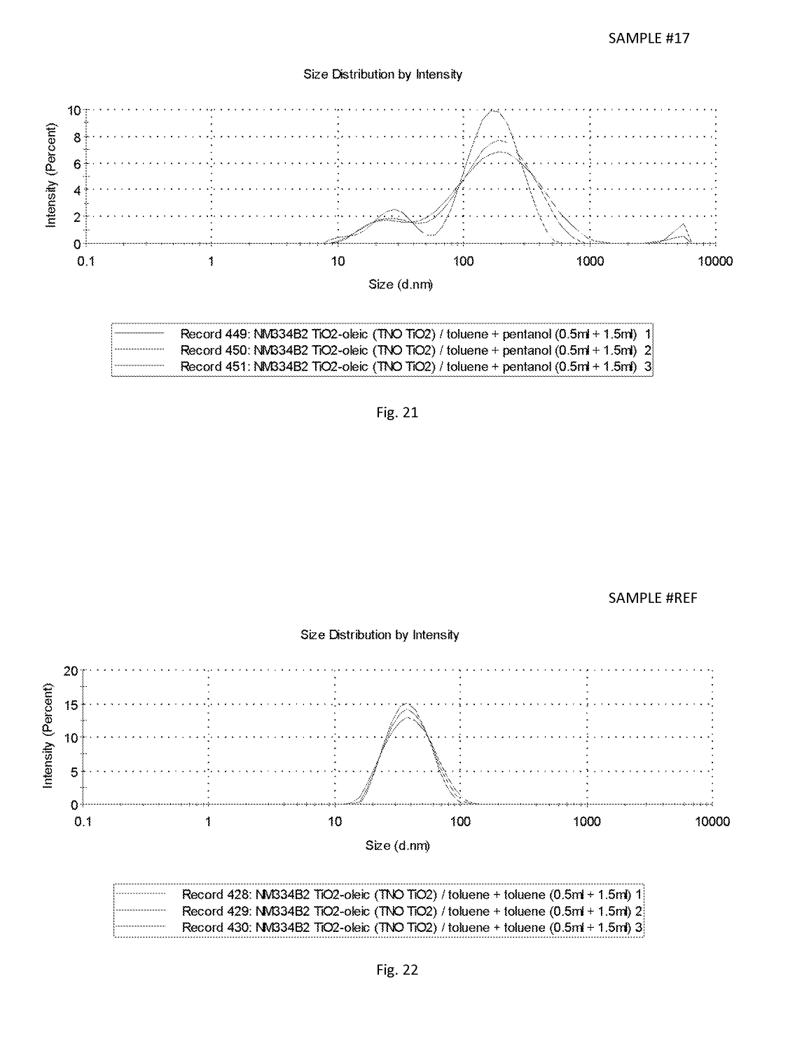

In FIGS. 1-22 the distributions of the measured intensities (%) vs particle size (nm) are shown. The presented results are the mean of 3 runs. The three distributions in each figures correspond to three runs. The mean results of 3 runs are summarized in Table 2 below. Some samples were measured twice or at different conditions (overnight) resulting in 22 results.

TABLE 2

| | Sample | Sample | Sample | Z-avg |
|---|---|---|---|---|
| # | label | description | treatment | (Intensity, nm) |
| 1 | NM334A1 | TiO2~oleic | Dispersion in | Peak 1: 473 nm (89%) |
| | | (Iolitec) | toluene | Peak 2: 38 nm (11%) |
| 2 | NM334B1 | TiO2~oleic (TNO, | Dispersion in | Peak 1: 76 nm (77%) |
| | | RJ110313-1) | toluene | Peak 2: 12 nm (23%) |
| 3 | NM334B2 | TiO2~oleic (TNO, | Dispersion in | 40 nm |
| | | RJ110313-1) | toluene | |
| 4 | NM334C1 | TiO2~oleic | Dispersion in | Peak 1: 129 nm (97%) |
| | | (Plasmachem) | toluene | Peak 2: 18 nm (3%) |
| 5 | NM334C2 | TiO2~oleic | Dispersion in | Peak 1: 133 nm (94%) |
| | | (Plasmachem) | toluene | Peak 2: 3463 nm (6%) |
| 6 | NM334B2 | TiO2~oleic (TNO, | 0.5 ml/toluene + | 28.4 nm |
| | | RJ110313-1) | 0.5 ml Hexane | |
| 7 | NM334B2 | TiO2~oleic (TNO, | 0.5 ml/toluene + | 29.4 nm |
| | | RJ110313-1) | 1.0 ml Hexane | |
| 8 | NM334B2 | TiO2~oleic (TNO, | 0.5 ml/toluene + | 31.5 nm |
| | | RJ110313-1) | 1.5 ml Hexane | |
| 8A | NM334B2 | TiO2~oleic (TNO, | 0.5 ml/toluene + | 84.5 nm |
| | | RJ110313-1) | 1.5 ml Hexane | |
| | | | OVERNIGHT | |
| 9 | NM334B2 | TiO2~oleic (TNO, | 0.5 ml/toluene + | 39.1 nm |
| | | RJ110313-1) | 0.5 ml THF | |
| 10 | NM334B2 | TiO2~oleic (TNO, | 0.5 ml/toluene + | 39.6 nm |
| | | RJ110313-1) | 1.0 ml THF | |
| 11 | NM334B2 | TiO2~oleic (TNO, | 0.5 ml/toluene + | 38.5 nm |
| | | RJ110313-1) | 1.5 ml THF | |
| 12 | NM334B2 | TiO2~oleic (TNO, | 0.5 ml/toluene + | Peak 1: 82 nm (81%) |
| | | RJ110313-1) | 0.5 ml Ethanol | Peak 2: 11 nm (17%) |
| 13 | NM334B2 | TiO2~oleic (TNO, | 0.5 ml/toluene + | Peak 1: 82 nm (81%) |
| | | RJ110313-1) | 1.0 ml Ethanol | Peak 2: 11 nm (17%) |
| 14 | NM334B2 | TiO2~oleic (TNO, | 0.5 ml/toluene + | Peak 1: 102 nm (81%) |
| | | RJ110313-1) | 1.5 ml Ethanol | Peak 2: 19 nm (17%) |
| 12A | NM334B2 | TiO2~oleic (TNO, | 0.5 ml/toluene + | Peak 1: 70 nm (83%) |
| | | RJ110313-1) | 0.5 ml Ethanol | Peak 2: 10 nm (17%) |
| | | | DUPLO | |
| 13A | NM334B2 | TiO2~oleic (TNO, | 0.5 ml/toluene + | Peak 1: 96 nm (84%) |
| | | RJ110313-1) | 1.0 ml Ethanol | Peak 2: 14 nm (10%) |
| | | | DUPLO | |
| 14A | NM334B2 | TiO2~oleic (TNO, | 0.5 ml/toluene + | Peak 1: 96 nm (84%) |
| | | RJ110313-1) | 1.5 ml Ethanol | Peak 2: 13 nm (15%) |
| | | | DUPLO | |
| 15 | NM334B2 | TiO2~oleic (TNO, | 0.5 ml/toluene + | Peak 1: 91 nm (99%) |
| | | RJ110313-1) | 0.5 ml Pentanol | |
| 16 | NM334B2 | TiO2~oleic (TNO, | 0.5 ml/toluene + | Peak 1: 188 nm (82%) |
| | | RJ110313-1) | 1.0 ml Pentanol | Peak 2: 30 nm (18%) |
| 17 | NM334B2 | TiO2~oleic (TNO, | 0.5 ml/toluene + | Peak 1: 188 nm (81%) |
| | | RJ110313-1) | 1.5 ml Pentanol | Peak 2: 27 nm (16%) |
| REF | NM334B2 | TiO2~oleic (TNO, | 0.5 ml/toluene + | 43 nm |
| | | RJ110313-1) | 1.5 ml Toluene | |
| | | | REFERENCE | |

In the above examples, dispersions of oleic acid modified TiO₂ nanoparticles in toluene were treated with different types of solvents (non-polar (Hexane), polar aprotic (THF) and polar protic (EtOH, pentanol)). The modified commercially available TiO₂ nanoparticles show larger size distributions than the in situ synthesized modified nanoparticles. Iolitec nanoparticles (sample #1 in Table 2) show sedimentation in toluene after modification indicating large particles. Samples prepared as NM334B2 show the most optimal mono-modal size distribution in toluene after oleic acid modification.

The examples also confirm that bimodal distributions can be obtained by addition of polar protic solvents e.g. ethanol and propanol. The particle size shifts from ˜40 nm monomodal peak value to a bimodal distribution containing particles (aggregates) with peaks of ˜20 nm and ˜100 nm. Addition of hexane and THF does not affect the particle size distribution to a large extent and bimodal distribution could not be obtained using these solvents.

1. A nanocomposite comprising inorganic primary nanoparticles having a particle size of less than 10 nm, said primary nanoparticles forming agglomerates dispersed in a polymer matrix, wherein the nanocomposite comprises 10-80 wt. % of the agglomerates having a particle size of less than 30 nm and less than 20 wt % of the agglomerates haying a particle size of at least 100 nm based on the total weight of the agglomerates.

2. The composition according to claim 1, wherein the material of the nanoparticles has a refractive index of at least 2.

3. The nanocomposite according to claim 2, wherein the nanoparticles comprise TiO₂, ZrO₂, amorphous silicon, PbS, ZnS, or combinations thereof.

4. The nanocomposite according to claim 3, wherein the nanoparticles comprise titanium oxide.

5. The nanocomposite according to claim 2, further comprising nanoparticles with a refractive index of less than 2.

6. The nanocomposite according to claim 5, comprising nanoparticles comprising CaO.

7. The nanocomposite according to claim 1, wherein the nanoparticles further comprise a surface modifier selected from a group consisting of phosphonic acids, boronic acid, carboxylic acids and amines.

8. The nanocomposite according to claim 7, wherein the surface modifier is oleic acid.

9. The nanocomposite according to claim 1, wherein the volume percentage of the nanoparticles in the matrix is 10-80%.

10. The nanocomposite according to claim 1, wherein the matrix has a refractive index of 1.4-1.6.

11. The nanocomposite according to claim 1, wherein the polymer matrix is one of aliphatic or aromatic epoxy acrylates, urethane acrylates, polyester acrylates, polyether acrylates, saturated hydrocarbon acrylates, polysiloxanes, polyimides or a mixture thereof.

12. The nanocomposite according to claim 1, wherein the size ratio D₂/D₁ of the two highest peaks in the particle size distribution pattern measured by Dynamic Light Scattering is in the range 5.5-8.

13. The nanocomposite according to claim 1, which composition is in the finial of a layer with a thickness of 1-1000 micron.

14. Method of manufacturing the nanocomposite according to claim 1, comprising the steps of:
(a) providing a dispersion of nanoparticles of an inorganic material with a hydrophobically modified surface in a medium, wherein the dispersion comprises 10-80 wt % of particles having a particle size of less than 30 nm and less than 20 wt. % of particles having a particle size of at least 100 nm, based on the total weight of the agglomerates,
(b) introducing the dispersion of the modified nanoparticles into a curable organic substance, and
(c) curing the organic substance.

15. The method according to claim 14, wherein step (a) comprises:
(i) providing of a dispersion of inorganic nanoparticles having a monomodal particle size distribution,
(ii) treating of the nanoparticles with a surface modifier to make these hydrophobic, and
(iii) adding a polar erotic solvent to obtain a dispersion of modified inorganic particles having a plurimodal particle size distribution.

16. The method according to claim 14, comprising the steps of:
(a) providing a dispersion of nanoparticles of an inorganic material in an aqueous medium, wherein the dispersion comprises 10-80 wt % of particles having a particle size of less than 30 nm and less than 20 wt. % of particles having a particle size of at least 400 nm, based on the total weight of the agglomerates,
(b) adding a surface modifier to the dispersion thereby obtaining modified nanoparticles,
(c) dispersing the modified nanoparticles in a curable organic substance, and
(d) curing the organic substance.

17. The method according to claim 16, wherein step (a) comprises the following steps:
(i) providing a dispersion of primary nanoparticles of an inorganic material in an aqueous medium, said primary nanoparticles having a particle size of less than 10 nm,
(ii) adjusting the to a value below 4 thereby forming agglomerates having a particle size of less than 30 nm, and
(iii) adjusting the pH to a value at least 4 thereby forming agglomerates having a particle size of at least 400 nm.

18. The method according to claim 14, further comprising a step of forming a layer of the curable organic substance comprising dispersed therein the modified nanoparticles, which step precedes the step of curing the composition.

19. Nanocomposite obtainable by the method of claim 14.

20. A barrier structure for an electronic device, comprising the nanocomposite layer according to claim 13 between two inorganic layers.

21. The barrier structure according to claim 20, wherein the inorganic layers comprise SiN.

22. An organic light-emitting diode (OLED) comprising:
a cathode layer
an organic electroluminescent layer
an anode layer, and
at least one barrier structure according to claim 20.

23. The OLED according to claim 22, comprising two bather structures according to claim 20, wherein one bather structure is placed on the outer side of the cathode layer and the other barrier structure is placed on the outer side of the anode layer.
